(19) United States
(12) Patent Application Publication
(10) Pub. No.: US 2010/0319621 A1
(43) Pub. Date: Dec. 23, 2010

(54) PLASMA PROCESSING APPARATUS AND PLASMA PROCESSING METHOD

(75) Inventors: Sang-Ho Woo, Icheon-si (KR); Il-Kwang Yang, Yongin-si (KR)

Correspondence Address: LRK Patent Law Firm, 1952 Gallows Rd, Suite 200, Vienna, VA, 22182, US

(73) Assignee: Eugene Technology Co., Ltd., Yongin-si (KR)

(21) Appl. No.: 12/865,722

(22) PCT Filed: Feb. 12, 2009
(86) PCT No.: PCT/KR2009/000655

§ 371 Date: Jul. 31, 2010

(30) Foreign Application Priority Data
Feb. 13, 2008 (KR) 10-2008-0013122

(51) Int. Cl. H01L 21/205

(52) U.S. Cl. 118/723 R

(57) ABSTRACT

A plasma processing apparatus includes a chamber providing an interior space where a process is performed upon a target; and a plasma generating unit generating an electric field in the interior space to generate plasma from a source gas supplied to the interior space. The plasma generating unit includes an upper source disposed substantially parallel to an upper surface of the chamber, an upper generator connected to the upper source to supply a first current to the upper source, a lateral source surrounding a lateral side of the chamber, and a lateral generator connected to the lateral source to supply a second current to the lateral source. The plasma generating unit further includes an upper matcher disposed between the upper generator and the upper source, and a lower matcher disposed between the lateral generator and the lateral source.

### TECHNICAL FIELD

The present invention relates to a method and apparatus for plasma processing, and more particularly to a method of processing a target in a chamber using plasma.

### BACKGROUND ART

A semiconductor device includes various layers on a silicon substrate, and such layers are deposited thereon through a deposition process. In the deposition process, there are some critical issues that are important in evaluation of deposited films and selection of a deposition method.

The first issue is plurality of the deposited film. This refers to a composition, a contamination level, a defect density, and mechanical/electrical properties. The composition of the film can vary depending on deposition conditions, which are very important to achieve a specific composition.

The second issue is a uniform thickness across a wafer. Particularly, the thickness of a film deposited on a non-planar pattern having a step is very important. Uniformity in thickness of the deposited film is determined by step-coverage, which is defined as a ratio of the minimum thickness of a film deposited on the step to the thickness of the film deposited on an upper surface of the pattern.

Another issue relating to deposition is space filling. This includes gap filling that fills a gap between metal lines with an insulating film such as an oxide film. The gap is provided to insulate the metal lines physically and electrically.

Among these issues, uniformity is one significant issue relating to the deposition process, and a non-uniform film causes a high electrical resistance of the metal line and a high possibility of mechanical damage.

### DISCLOSURE OF INVENTION

### Technical Problem

An aspect of the present invention is to provide a plasma processing apparatus and method capable of securing process uniformity.

Other aspects of the present invention will become more apparent from the detailed descriptions in conjunction with accompanying drawings.

### Technical Solution

In accordance with an aspect of the present invention, a plasma processing apparatus includes: a chamber providing an interior space where a process is performed upon a target; and a plasma generating unit generating an electric field in the interior space to generate plasma from a source gas supplied to the interior space, wherein the plasma generating unit includes an upper source disposed substantially parallel to an upper surface of the chamber; an upper generator connected to the upper source to supply a first current to the upper source; a lateral source surrounding a lateral side of the chamber; and a lateral generator connected to the lateral source to supply a second current to the lateral source.

The plasma generating unit may further include: an upper matcher disposed between the upper generator and the upper source; and a lower matcher disposed between the lateral generator and the lateral source.

The upper source may include a first upper source, a second upper source having substantially the same shape as the first upper source and having a preset phase difference from the first upper source, and a third upper source having substantially the same shape as the first and second upper source and having a preset phase difference from the second upper source.

The chamber may include a process chamber where a process is performed by the plasma, the process chamber being provided with a support member on which the target is placed; and a generation chamber located above the process chamber to allow the plasma to be generated by the plasma generating unit, wherein the upper source is disposed substantially parallel to an upper surface of the generation chamber, and the lateral source is provided at a lateral side of the generation chamber.

In accordance with another aspect of the present invention, there is provided a plasma processing method with an upper source disposed to be substantially parallel to an upper surface of a chamber and a lateral source disposed to surround a lateral side of the chamber, the method including: generating plasma in an interior space of the chamber by supplying a first current to the upper source through an upper source and supplying a second current to the lateral source through a lateral source; and processing a target provided inside the chamber using the generated plasma.

### Advantageous Effects

According to exemplary embodiments of the present invention, it is possible to generate plasma with uniform density in a chamber. Further, a target can be processed with uniformity by plasma.

### BRIEF DESCRIPTION OF DRAWINGS

The above and other aspects, features and advantages of the present invention will be more clearly understood from the detailed description taken in conjunction with the accompanying drawings, in which:

FIG. 1 is a schematic view of a plasma processing apparatus according to an exemplary embodiment of the present invention;

FIGS. 2 to 4 are views of an upper source of FIG. 1;

FIGS. 5 to 7 are views of a lateral source of FIG. 1;

FIG. 8 is a view of the interior of a plasma source of FIGS. 1; and

FIG. 9 is a view of a connector connected to the upper source of FIG. 1.

### BEST MODE FOR CARRYING OUT THE INVENTION

Exemplary embodiments of the present invention will now be described in more detail with reference to the accompanying drawings. However, it should be noted that the present invention is not limited to the embodiments and can be realized in various forms. The embodiments are given by way of illustration for full understanding of the present invention by those skilled in the art. Accordingly, the drawings are not to precise scale for clear description of the present invention.

Herein, an inductively coupled plasma (ICP) based plasma process will be described by way of example, but the present invention can be applied to various plasma processes. Further, a substrate will be described below as an example, but the present invention can be applied to various targets.

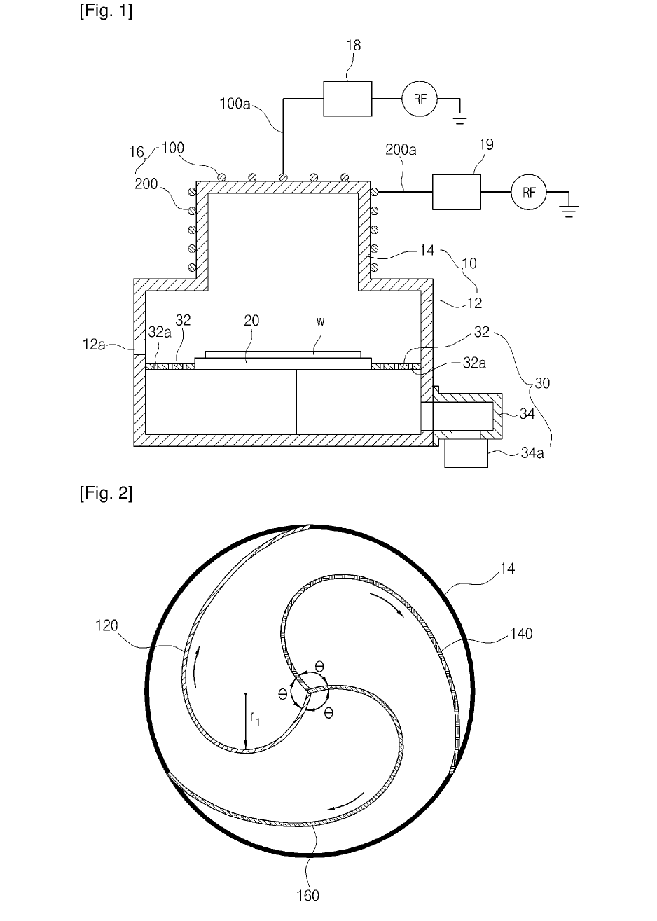

FIG. 1 is a schematic view of a plasma processing apparatus according to an exemplary embodiment of the present invention.

A plasma processing apparatus includes a chamber 10 having an interior space where a process is performed upon a substrate W. The chamber 10 is divided into a process chamber 12 and a generation chamber 14. In the process chamber 12, a process is performed upon the substrate, and in the generation chamber 14, plasma is generated from a source gas supplied from the outside.

A support plate 20 is disposed inside the process chamber 12 in which the substrate W is placed on the support plate 20. The substrate W is put into the process chamber 12 through an inlet 12a formed at one side of the process chamber 12, and is then placed on the support plate 20. The support plate 20 may be an electrostatic chuck (E-chuck) and may be provided with a separate helium (He) rear cooling system (not shown) to precisely control temperature of a wafer placed on the support plate 20.

The generation chamber 14 is provided with a plasma source 16 at upper and peripheral surfaces thereof. The plasma source 16 includes an upper source disposed at the upper surface of the generation chamber 14, and a lateral source 200 disposed at the peripheral surface of the generation chamber 14. The upper source 100 is connected to a radio frequency (RF) generator through an upper input line 100a, and an upper matcher 18 is provided between the upper source 100 and the RF generator. The lateral source 200 is connected to another RF generator through a lateral input line 200a, and a lateral matcher 19 is provided between the lateral source 200 and the RF generator. The upper matcher 18 and the lateral matcher 19 are provided for impedance matching.

An RF current supplied through the RF generator connected to the upper matcher 18 is supplied to the upper source 100, and an RF current supplied through the RF generator connected to the lateral matcher 19 is supplied to the lateral source 200. The upper source 100 and the lateral source 200 transform the RF current into a magnetic field, and generate plasma from source gas supplied into the chamber 10.

At this time, the upper source 100 and the lateral source 200 are connected to the separate RF generators, and thus separate RF currents are supplied to the upper source 100 and the lateral source 200, respectively. Thus, if the RF generator connected to the upper matcher 18 and the RF generator connected to the lateral matcher 19 are adjusted in different manners, the RF current supplied to the upper source 100 and the RF current supplied to the lateral source 200 may have different intensities.

With this configuration, process uniformity is adjustable with respect to the substrate W placed on the support plate 20. For example, if the upper source 100 corresponds to the center of the substrate W and the lateral source 200 corresponds to the edge of the substrate W, the uniformity at the center of the substrate W is higher or lower than the uniformity at the edge of the substrate W, the RF current supplied to the upper source 100 may be decreased or increased, or the RF current supplied to the lateral source 200 may be increased or decreased. In other words, the RF current supplied to the upper source 100 and the RF current supplied to the later source 200 are independently adjustable, thereby securing process uniformity.

The process chamber 12 is connected at one side thereof to an exhaust line 34, and a pump 34a is connected to the exhaust line 34. Plasma, by-products, and the like are exhausted to the outside of the chamber 10 via the exhaust line 34, and the pump 34a forces them to be exhausted.

The plasma, by-products and the like inside the chamber 10 are introduced into the exhaust line 34 via an exhaust plate 32. The exhaust plate 32 is disposed outside the support plate 20 and substantially parallel with the support plate 20. The plasma, the by-products and the like inside the chamber 10 are introduced into the exhaust line 34 via exhaust holes 32a formed on the exhaust plate 32.

FIGS. 2 to 4 show the upper source 100 of FIG. 1.

Referring to FIGS. 2 to 4, the upper source 100 includes a first upper source 120, a second upper source 140 and a third upper source 160. The first to third upper sources 120, 140 and 160 have substantially the same shape, and are arranged at equal angles to one another. Accordingly, the first to third upper sources 120, 140 and 160 have substantially the same phase difference)(θ=60°).

FIG. 2 shows the upper source 100 according to an exemplary embodiment of the present invention. Referring to FIG. 2, the first upper source 120 extends with a preset curvature (radius of curvature=r₁) from the center of the upper surface of the generation chamber 14 toward the edge of the upper surface of the generation chamber 14. The length of the first upper source 120 may be varied depending on the radius of curvature, and an operator may change the radius of curvature according to processes. The upper input line 100a is connected to one end of the first to third upper sources 120, 140 and 160 placed at the center of the upper surface of the generation chamber 14. Thus, the RF current supplied to the upper source 100 is transferred from the center of the upper surface of the generation chamber 14 toward the edge of the upper surface of the generation chamber 14 through the first to third upper sources 120, 140 and 160 while generating a clockwise spiral.

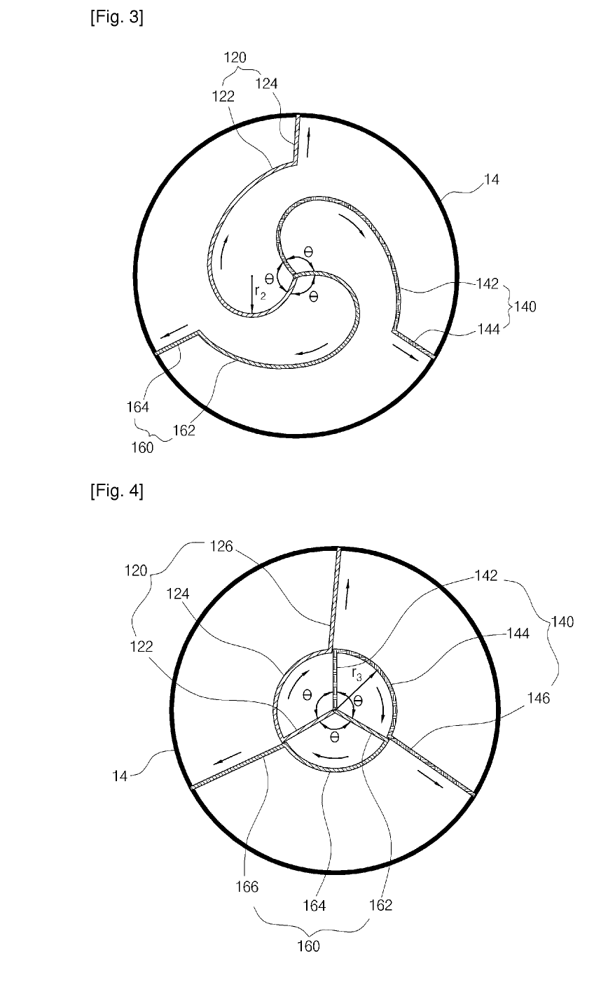

FIG. 3 shows the upper source 100 according to another exemplary embodiment of the present invention. Referring to FIG. 3, the first upper source 120 includes a first center source 122 and a first edge source 124. The first center source 122 extends with a preset curvature (radius of curvature=r₂) from the center of the upper surface of the generation chamber 14 toward the edge of the upper surface of the generation chamber 14. The first edge source 124 extends radially from the end of the first center source 122 toward the edge of the upper surface of the generation chamber 14. The length of the first upper source 120 may be varied depending on the radius of curvature and the length of the first edge source 124, and an operator may change the radius of curvature according to processes. The foregoing upper input line 100a is connected to one end of the first to third upper sources 120, 140 and 160 placed at the center of the upper surface of the generation chamber 14. Thus, the RF current supplied to the upper source 100 is transferred from the center of the upper surface of the generation chamber 14 toward the edge of the upper surface of the generation chamber 14 through the first to third center sources 122, 142 and 162 while generating a clockwise spiral, and is then radially transferred toward the edge of the upper surface of the generation chamber 14 through the first to third edge sources 124, 144 and 164.

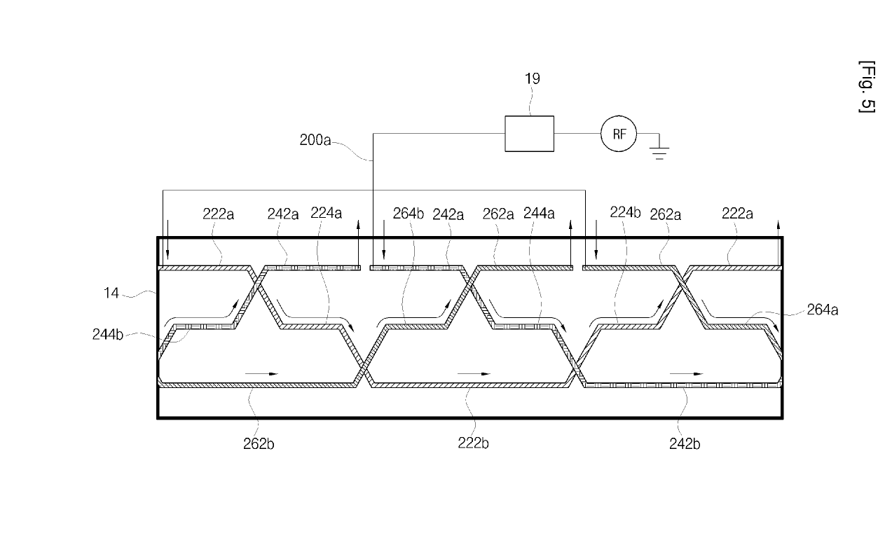

FIG. 4 shows the upper source 100 according to still another exemplary embodiment of the present invention. Referring to FIG. 4, the first upper source 120 includes a first center source 122, a first circular source 124, and a first edge source 126. The first center source 122 radially extends from the center of the upper surface of the generation chamber 14 toward the edge of the upper surface of the generation chamber 14. The first circular source 124 extends from the end of the first center source 122 and is shaped like an arc of a circle having a radius equal to the length r₃ of the first center source 122. The first edge source 126 radially extends from the end of the first circular source 124 toward the edge of the upper surface of the generation chamber 14. On the other hand, the length of the first upper source 120 may be varied depending on the length r₃ of the first center source 122, and an operator may change the radius of curvature according to processes. The upper input line 100a is connected to one end of the first to third upper sources 120, 140 and 160 placed at the center of the upper surface of the generation chamber 14. Thus, the RF current supplied to the upper source 100 is transferred from the center of the upper surface of the generation chamber 14 toward the edge of the upper surface of the generation chamber 14 through the first to third center sources 122, 142 and 162, and is then radially transferred toward the edge of the upper surface of the generation chamber 14 through the first to third edge sources 126, 146 and 166 after rotating by a preset angle through the first to third circular sources 124, 144 and 164.

The aforementioned upper source 100 generates plasma with uniform density in the generation chamber 14 in the radial direction of the upper surface of the generation chamber 14. The lateral source 200 is disposed at the peripheral surface of the generation chamber 14, so that the density of plasma generated by the lateral source 200 increases moving to the peripheral surface of the generation chamber 14, but decreases moving away from the peripheral surface of the generation chamber 14. The upper source 100 is disposed from the center of the upper surface of the generation chamber 14 to the edge of the upper surface of the generation chamber 14, so that the density of plasma generated by the upper source 100 is uniform along the radial direction of the upper surface of the generation chamber 14. On the other hand, the first to third upper sources 120, 140 and 160 shown in FIGS. 2 to 4 are insulated from one another.

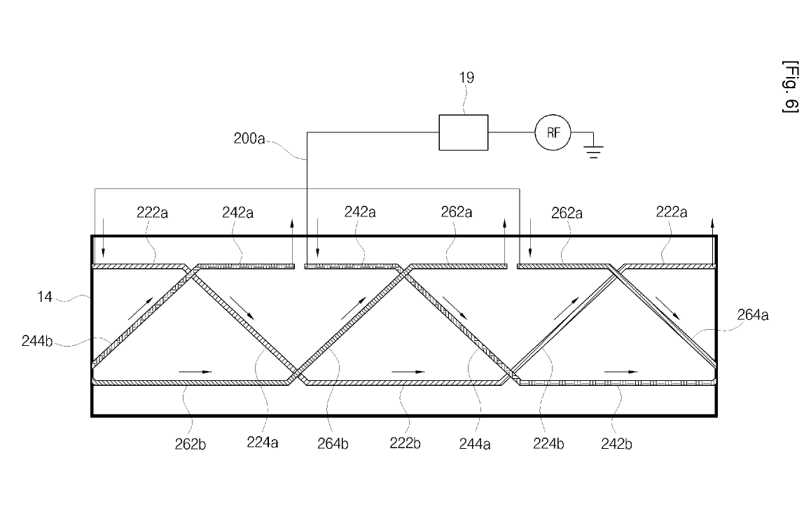

FIGS. 5 to 7 show the lateral source 200 of FIG. 1. The generation chamber 14 of FIGS. 5 to 7 is obtained by developing the peripheral surface of the generation chamber 14 of FIG. 1, and the lateral source 200 of FIGS. 5 to 7 is disposed at the peripheral surface of the generation chamber 14. Referring to FIGS. 5 to 7, the lateral source 200 includes a first lateral source 220, a second lateral source 240 and a third lateral source 260, and the first to third lateral sources 220, 240 and 260, each of which has one end connected to the end of a lateral input line 200a, have substantially the same phase difference) (θ=60°). The first to third lateral sources 220, 240 and 260 have substantially the same shape and the RF current flows through the first to third lateral sources 220, 240 and 260 from one side to the other side of the generation chamber 14. In this embodiment, the RF currents flow through the first to third lateral sources 220, 240 and 260 in the same direction, but may alternatively flow in different directions from one another.

FIG. 5 shows the lateral source 200 according to an exemplary embodiment of the present invention. Referring to FIG. 5, the first lateral source 220 includes a first descent source 222 and a first ascent source 224. The first descent source 222 has one end connected to the end of the lateral input line 200a, and extends to be downwardly inclined from the top toward the bottom of the generation chamber 14. The first ascent source 224 has one end connected to the end of the first descent source 222, and extends to be upwardly inclined from the bottom toward the top of the generation chamber 14. The first lateral source 220 shown in FIG. 5 includes the single first descent source 222 and the single first ascent source 224, but the present invention is not limited thereto. Alternatively, a plurality of first descent sources 222 and a plurality of first ascent sources 224 may be provided alternately. As described above, the RF current is supplied to the first to third lateral sources 220, 240 and 260 each connected to the lateral input line 200a. Then, the RF current flows from the top toward the bottom of the generation chamber 14 through the first to third descent sources 222, 242 and 262, and flows from the bottom to the top of the generation chamber 14 through the first to third ascent sources 224, 244 and 264.

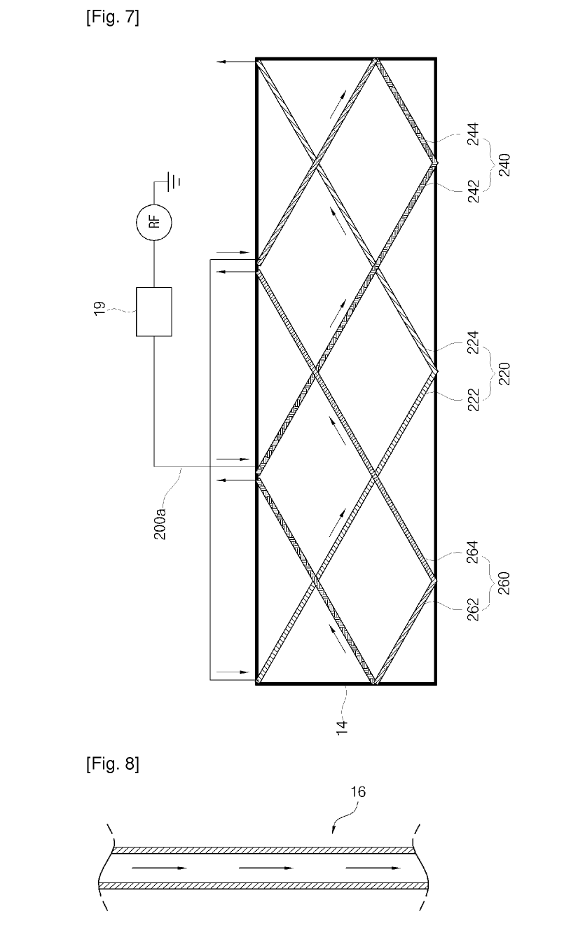

FIG. 6 shows the lateral source 200 according to another exemplary embodiment of the present invention, and FIG. 7 is a modification of FIG. 6. Referring to FIG. 6, the first lateral source 220 includes a first upside source 222a, a first downside source 222b, a first descent source 224a and a first ascent source 224b. The first upside source 222a has one end connected to the end of the lateral input line 200a, and extends to be substantially parallel with the upper surface of the generation chamber 14 in a direction from one side toward the other side of the generation chamber 14. The first downside source 222b extends to be substantially parallel with the first upside source 222a in a direction from one side toward the other side of the generation chamber 14. The first upside source 222a and the first downside source 222b are connected through the first descent source 224a extending to be downwardly inclined from the first upside source 222a and the first ascent source 224b extending to be upwardly inclined from the first downside source 222b. As an alternative to the first lateral source 220 shown in FIG. 5, a plurality of first upside sources 222a, a plurality of first downside sources 222b, a plurality of first descent sources 224a, and a plurality of first upside sources 224b may be alternately provided. As described above, the RF current is supplied to the first to third lateral sources 220, 240 and 260 each connected to the lateral input line 200a. Then, the RF current flows from one side toward the other side of the generation chamber 14 through the first to third upside sources 222a, 242a and 262a, and flows from the top to the bottom of the generation chamber 14 through the first to third descent sources 224a, 244a and 264a. Then, the RF current flows from one side toward the other side of the generation chamber 14 through the first to third downside sources 222b, 242b and 262b, and flows from the bottom to the top of the generation chamber 14 through the first to third ascent sources 224a, 244a and 264a.

The aforementioned lateral source 200 generates plasma with uniform density in the generation chamber 14 in the vertical direction of the generation chamber 14. The RF current flowing along the lateral source 200 alternates between the top and the bottom of the generation chamber 14 along the peripheral surface of the generation chamber 14, so that a magnetic field generated by the RF current is uniform in the vertical direction of the generation chamber 14, and also plasma generated by the magnetic field has uniform density in the vertical direction of the generation chamber 14. In the meantime, the first to third lateral sources 220, 240 and 260 shown in FIGS. 5 to 7 are insulated from one another.

FIG. 8 shows the interior of the plasma source 16 of FIG. 1. Since the RF current flows through the plasma source 16, the temperature of the plasma source 16 may increase. To control the temperature of the plasma source 16, a refrigerant may be supplied to the interior of the plasma source 16, and a chiller (not shown) may be used for controlling the refrigerant to have a preset temperature.

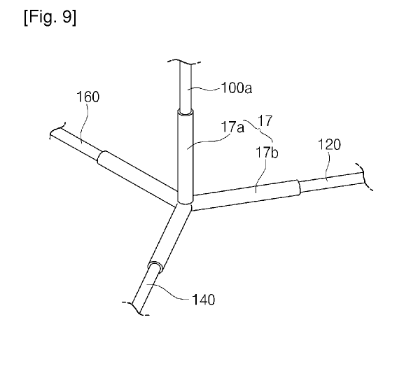

FIG. 9 shows a connector 17 connected to the upper source 100 of FIG. 1. The connector 17 includes an upper connector 17a and a plurality of lower connectors 17b. The upper connector 17a is connected to the upper input line 100a, and the lower connectors 17b are connected to the first to third upper sources 120, 140 and 160, respectively.

Although the present invention has been described with reference to the embodiments and the accompanying drawings, this invention is not limited to these embodiments. Further, it should be understood that various modifications, additions and substitutions can be made by a person having ordinary knowledge in the art without departing from the scope and spirit of the invention as disclosed in the accompanying claims.

1. A plasma processing apparatus comprising:
a chamber providing an interior space where a process is performed upon a target; and
a plasma generating unit generating an electric field in the interior space to generate plasma from a source gas supplied to the interior space,
the plasma generating unit comprising:
an upper source disposed substantially parallel to an upper surface of the chamber;
an upper generator connected to the upper source to supply a first current to the upper source;
a lateral source surrounding a lateral side of the chamber; and
a lateral generator connected to the lateral source to supply a second current to the lateral source.

2. The plasma processing apparatus according to claim 1, wherein the plasma generating unit further comprises:
an upper matcher disposed between the upper generator and the upper source; and
a lower matcher disposed between the lateral generator and the lateral source.

3. The plasma processing apparatus according to claim 1, wherein the upper source comprises a first upper source, a second upper source having substantially the same shape as the first upper source and having a preset phase difference from the first upper source, and a third upper source having substantially the same shape as the first and second upper source and having a preset phase difference from the second upper source.

4. The plasma processing apparatus according to claim 1, wherein the chamber comprises:
a process chamber where a process is performed by the plasma, the process chamber being provided with a support member on which the target is placed; and
a generation chamber located above the process chamber to allow the plasma to be generated by the plasma generating unit,
wherein the upper source is disposed substantially parallel to an upper surface of the generation chamber, and the lateral source is provided at a lateral side of the generation chamber.

5. A plasma processing method with an upper source disposed to be substantially parallel to an upper surface of a chamber and a lateral source disposed to surround a lateral side of the chamber, the method comprising:
generating plasma in an interior space of the chamber by supplying a first current to the upper source through an upper source and supplying a second current to the lateral source through a lateral source; and
processing a target provided inside the chamber using the generated plasma.

6. The plasma processing apparatus according to claim 2, wherein the upper source comprises a first upper source, a second upper source having substantially the same shape as the first upper source and having a preset phase difference from the first upper source, and a third upper source having substantially the same shape as the first and second upper source and having a preset phase difference from the second upper source.

7. The plasma processing apparatus according to claim 2, wherein the chamber comprises:
a process chamber where a process is performed by the plasma, the process chamber being provided with a support member on which the target is placed; and
a generation chamber located above the process chamber to allow the plasma to be generated by the plasma generating unit,
wherein the upper source is disposed substantially parallel to an upper surface of the generation chamber, and the lateral source is provided at a lateral side of the generation chamber.
